(19) United States
(12) Patent Application Publication
(10) Pub. No.: US 2022/0416215 A1
(43) Pub. Date: Dec. 29, 2022

(54) DISPLAY PANEL AND DISPLAY DEVICE

(71) Applicants: WUHAN TIANMA MICROELECTRONICS CO., LTD., Wuhan (CN); Wuhan Tianma Microelectronics Co., Ltd. Shanghai Branch, Shanghai (CN)

(72) Inventor: Jiamin Guo, Wuhan (CN)

(73) Assignees: WUHAN TIANMA MICROELECTRONICS CO., LTD., Wuhan (CN); Wuhan Tianma Microelectronics Co., Ltd. Shanghai Branch, Pudong New District, Shanghai (CN)

(21) Appl. No.: 17/929,622

(22) Filed: Sep. 2, 2022

(30) Foreign Application Priority Data
May 31, 2022 (CN) 202210613236.7

(51) Int. Cl. H01L 51/52; H01L 27/32

(52) U.S. Cl. CPC H01L 51/5275; H01L 27/3218; H01L 51/5253; H01L 27/3213

(57) ABSTRACT

Embodiments of the present disclosure provide a display panel and a display device. The display panel includes a substrate, sub-pixels located on a side of the substrate and including light-modulating sub-pixels and non-light-modulating sub-pixels, and light-modulating structures located on sides of the sub-pixels facing away from the substrate. The light-modulating structure includes light-extracting portions and a high refractive index layer. A first distance L1 between the light-extracting portion and the light-modulating sub-pixel closest to the light-extracting portion and a second distance L2 between the light-extracting portion and the non-light-modulating sub-pixel closest to the light-extracting portion satisfy L1<L2. The high refractive index layer is located on sides of the light-extracting portions facing away from the substrate and covers the sub-pixels and the light-extracting portions, and the high refractive index layer has a greater refractive index than that of the light-extracting portion.

### CROSS-REFERENCE TO RELATED APPLICATION

The present application claims priority to Chinese Patent Application No. 202210613236.7, filed on May 31, 2022, the content of which is incorporated herein by reference in its entirety.

### TECHNICAL FIELD

The present disclosure relates to the field of display technologies, and, particularly, relates to a display panel and a display device.

### BACKGROUND

With continuous development of display technology, the organic light-emitting diode (OLED) display panels are widely used in various electronic devices due to their advantages of self-luminescence, wide viewing angle, high contrast ratio, and low power consumption.

However, the OLED display panels in the related art have problems, such as low light extraction efficiency and color cast, which seriously affect the display performance.

### SUMMARY

A first aspect of the present disclosure provides a display panel. The display panel includes a substrate; sub-pixels located on a side of the substrate and including light-modulating sub-pixels and non-light-modulating sub-pixels; light-modulating structures located on sides of the sub-pixels facing away from the substrate, where each one of the light-modulating structures includes light-extracting portions and a high refractive index layer. In a direction perpendicular to a plane of the substrate, each of the light-extracting portions is located at a side of one of the light-modulating sub-pixels, and a first distance L1 between the light-extracting portion and one of the light-modulating sub-pixels closest to the light-extracting portion and a second distance L2 between the light-extracting portion and one of the non-light-modulating sub-pixels closest to the light-extracting portion satisfy L1<L2; and the high refractive index layer is located on sides of the light-extracting portions facing away from the substrate and covers the sub-pixels and the light-extracting portions, and the high refractive index layer has a refractive index greater than the light-extracting portion.

A second aspect of the present disclosure provides a display device. The display device includes the above-described display panel.

### BRIEF DESCRIPTION OF DRAWINGS

In order to more clearly illustrate technical solutions of embodiments of the present disclosure, the accompanying drawings used in the embodiments are briefly described below. The drawings described below are merely a part of the embodiments of the present disclosure. Based on these drawings, those skilled in the art can obtain other drawings.

FIG. 1 is a schematic diagram of a light transmission in the related art;

FIG. 2 is a top view of a display panel according to some embodiments of the present disclosure;

FIG. 3 is a cross-sectional view of FIG. 2 along line A1-A2 according to some embodiments of the present disclosure;

FIG. 4 is a schematic diagram of a light transmission according to some embodiments of the present disclosure;

FIG. 5 is another top view of a display panel according to some embodiments of the present disclosure;

FIG. 6 is a schematic diagram of a light-extracting portion according to some embodiments of the present disclosure;

FIG. 7 is another schematic diagram of a light transmission according to some embodiments of the present disclosure;

FIG. 8 is another schematic diagram of a light-extracting portion according to some embodiments of the present disclosure;

FIG. 9 is another schematic diagram of a light-extracting portion according to some embodiments of the present disclosure;

FIG. 10 is another schematic diagram of a light-extracting portion according to some embodiments of the present disclosure;

FIG. 11 is another schematic diagram of a light-extracting portion according to some embodiments of the present disclosure;

FIG. 12 is a schematic diagram of an arrangement of sub-pixels according to some embodiments of the present disclosure;

FIG. 13 is another schematic diagram of an arrangement of sub-pixels according to some embodiments of the present disclosure;

FIG. 14 is a schematic diagram illustrating positions of a light-extracting portion and a first support pillar according to some embodiments of the present disclosure;

FIG. 15 is a cross-sectional view of FIG. 14 along line B1-B2 according to some embodiments of the present disclosure;

FIG. 16 is another schematic diagram illustrating positions of a light-extracting portion and a first support pillar according to some embodiments of the present disclosure;

FIG. 17 is a cross-sectional view of FIG. 16 along line C1-C2 according to some embodiments of the present disclosure; and

FIG. 18 is a schematic diagram of a display device according to some embodiments of the present disclosure.

### DESCRIPTION OF EMBODIMENTS

In order to better understand the technical solutions of the present disclosure, the embodiments of the present disclosure are described in detail below with reference to the accompanying drawings.

It should be clear that the described embodiments are only some embodiments of the present disclosure, rather than all embodiments of the present disclosure. Based on the embodiments in the present disclosure, all other embodiments obtained by those of ordinary skill in the art fall within the protection scope of the present disclosure.

The terms used in the embodiments of the present disclosure are only for the purpose of describing specific embodiments, and are not intended to limit the present disclosure. As used in the embodiments of this application and the appended claims, the singular forms “a”, “an” and “the” are intended to include the plural forms as well, unless the context clearly dictates otherwise.

It should be understood that the term “and/or” used in this document is only an association relationship to describe the associated objects, indicating that there can be three relationships, for example, A and/or B, which can indicate that A alone, A and B, and B alone. The character “/” in the present description generally indicates that the related objects are an “or” relationship.

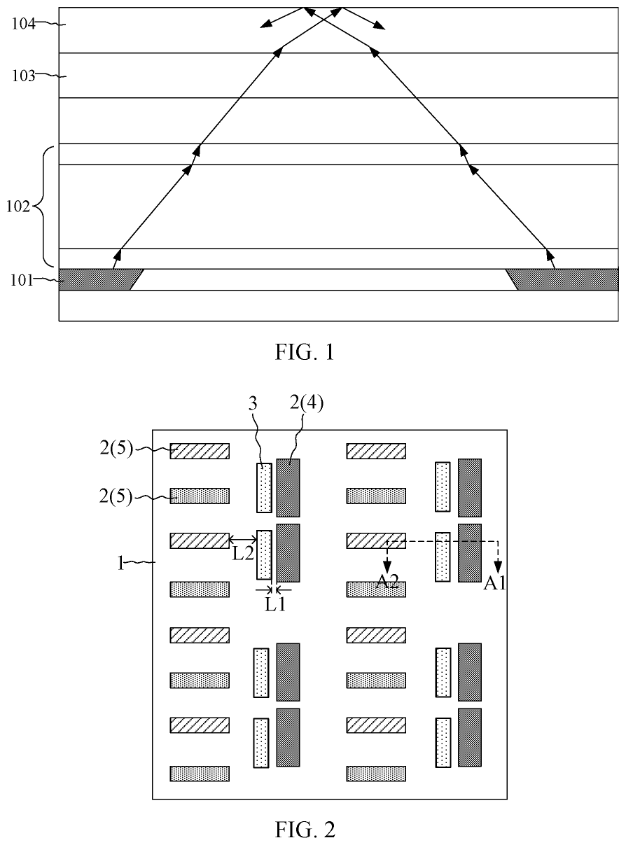

FIG. 1 is a schematic diagram of a light transmission in the related art. In the layer structure of a display panel in the related art, as shown in FIG. 1, the sub-pixel 101 is covered by an encapsulation layer 102, a polarizer 103, a cover 104, and so on. Therefore, when the light emitted by the sub-pixel 101 is transmitted outwards, it needs to be reflected and refracted by multiple layers. Due to the difference in optical properties of different layer materials, light will be lost inside the display panel in the form of total reflection during transmission. For example, the light can be totally reflected at an interface between the cover 104 and the air, resulting in the loss of a large amount of energy. In this way, the light that can finally exit the display panel only accounts for about 15% of the light emitted by the light-emitting element, resulting in a relatively low light extraction efficiency of the display panel.

In this regard, the present disclosure provides a display panel, which can effectively improve the light extraction efficiency of the display panel, and can also reduce the difference in service life attenuation between different sub-pixels, thereby effectively solving the problem of color cast.

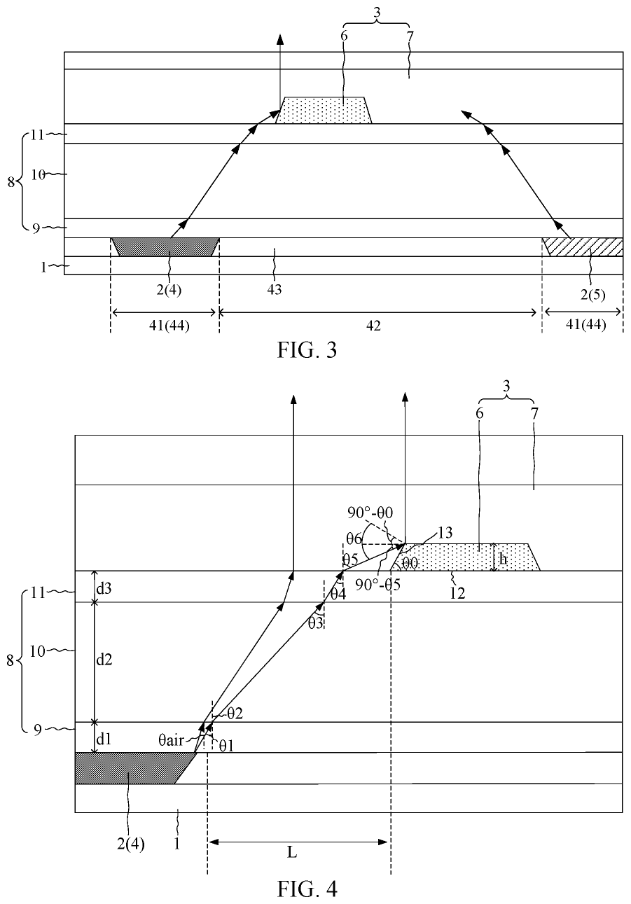

FIG. 2 is a top view of a display panel according to some embodiments of the present disclosure, and FIG. 3 is a cross-sectional view of FIG. 2 along line A1-A2 according to some embodiments of the present disclosure. As shown in FIG. 2 and FIG. 3, the display panel includes a substrate 1, multiple sub-pixels 2 located on a side of the substrate 1, and a light-modulating structure 3 located on a side of the sub-pixel 2 facing away from the substrate 1.

The multiple sub-pixels 2 include a light-modulating sub-pixel 4 and a non-light-modulating sub-pixel 5. Affected by the characteristics of the light-emitting material, different sub-pixels 2 have different luminous efficiencies.

The light-modulating structure 3 includes multiple light-extracting portions 6 and a high refractive index layer 7. In a direction perpendicular to a plane of the substrate 1, the light-extracting portion 6 is located at a side of the light-modulating sub-pixel 4, and a first distance L1 between the light-extracting portion 6 and the light-modulating sub-pixel 4 closest to this light-extracting portion 6 and a second distance L2 between the light-extracting portion 6 and the non-light-modulating sub-pixel 5 closest to this light-extracting portion 6 satisfy L1<L2. The high refractive index layer 7 is located at a side of the light-extracting portion 6 facing away from the substrate 1 and covers the sub-pixel 2 and the light-extracting portion 6. The high refractive index layer 7 has a greater refractive index than the light-extracting portion 6.

Referring to FIG. 3 again, the display panel has a pixel region 41 and a non-pixel region 42, the display panel includes a pixel definition layer 43. The pixel definition layer 43 includes an opening 44 configured to define the pixel region 41. From another perspective, the sub-pixel 2 in some embodiments of the present disclosure can be understood as the light-emitting layer in the light-emitting element, and the sub-pixel 2 is located in the opening 44 of the pixel definition layer 43, that is, the sub-pixel 2 is located in the pixel region 41. Therefore, in the following description, the positional relationship and distance relationship between the light-extracting portion 6 and the sub-pixels 2 can be understood as the positional relationship and distance relationship between the light-extracting portion 6 and the opening 44 of the pixel definition layer 43.

In some embodiments of the present disclosure, the description “in the direction perpendicular to the plane of the substrate 1, the light-extracting portion 6 is located at a side of the light-modulating sub-pixel 4” can be understood as “in the direction perpendicular to the plane of the substrate 1, an orthographic projection of the light-extracting portion 6 is located at a side of an orthographic projection of the light-modulating sub-pixel 4”, and “the distance between the light-extracting portion 6 and the sub-pixel 2” can be understood as “a distance between the orthographic projection of the light-extracting portion 6 and the orthographic projection of the sub-pixel 2”.

In the related art, for the sub-pixel 2 with a relatively low luminous efficiency, in order to enable such sub-pixels 2 to have a higher display brightness, a driving current flowing through such sub-pixel 2 is usually increased, but this can cause a large current density of such sub-pixel 2, which leads to rapid service life attenuation, and thus there is a significant difference in service life attenuation between such sub-pixel 2 and other sub-pixels 2, resulting in serious color cast in the display panel.

In the embodiments of the present disclosure, for the light-modulating sub-pixel 4, since the light-extracting portion 6 is located at a side of the light-modulating sub-pixel 4 and the light-extracting portion 6 is relatively close to the light-modulating sub-pixel 4, more light emitted by the pixel 4 can be transmitted to the light-extracting portion 6. With a difference between the refractive index of the high refractive index layer 7 and the refractive index of the light-extracting portion 6, an interface where the high refractive index layer 7 is in contact with the light-extracting portion 6, i.e., a side wall of the light-extracting portion 6, will form a totally reflective interface. When the light emitted by the light-modulating sub-pixel 4 reaches the interface, the light will be totally reflected at the interface, thereby changing its transmission direction, and making light originally not emitted from the panel to finally be emitted out of the display panel after being modulated by the light-modulating structure 3. It can be seen that in the embodiments of the present disclosure, the display brightness of the light-modulating sub-pixel 4 can be increased by using the light-modulating structure 3 to improve the light extraction efficiency of the light-modulating sub-pixel 4, so there is no need to increase the driving current provided to the light-modulating sub-pixel 4, which not only reduces the power consumption of the display panel, but also effectively reduces the current density of the light-modulating sub-pixel 4 and reduces its service life attenuation rate.

For the non-light-modulating sub-pixel 5, since the non-light-modulating sub-pixel 5 is far away from the light-extracting portion 6, the light emitted by the non-light-modulating sub-pixel 5 is difficult to be transmitted to the light-extracting portion 6, and the light-extracting portion 6 almost cannot affect the light output of the non-light-modulating sub-pixels 5, and thus cannot affect the service life attenuation rate of the non-light-modulating sub-pixels 5.

Therefore, in the embodiments of the present disclosure, by designing different distances between the light-extracting portion 6 and different sub-pixels 2, the light extraction efficiency of different sub-pixels 2 can be adjusted to different degrees by using the light-extracting portion 6. The technical solutions provided by the embodiments of the present disclosure can not only effectively improve the light extraction efficiency of the display panel, but also make the service life attenuation rates of different sub-pixels 2 tend to be consistent, thereby effectively improving the color cast phenomenon.

In some embodiments, referring to FIG. 3, the display panel includes an encapsulation layer 8 located between the sub-pixel 2 and the light-modulating structure 3. The encapsulation layer 8 includes a first inorganic encapsulation layer 9, an organic encapsulation layer 10 located on a side of the first inorganic encapsulation layer 9 facing away from the substrate 1, and a second inorganic encapsulation layer 11 located on a side of the organic encapsulation layer 10 facing away from the substrate 1.

FIG. 4 is a schematic diagram of a light transmission according to some embodiments of the present disclosure. As shown in FIG. 4, an incident angle of an outmost edge light emitted from the side of the light-modulating sub-pixel 4 close to the light-extracting portion 6 when the outmost edge light enters the organic encapsulation layer 10 through the first inorganic encapsulation layer 9 is θ1. If the most edge light is able to eventually exit from the display panel, θ1 satisfies: θ1 ∈(θₐᵢᵣ, δ2), where θₐᵢᵣ denotes a maximum incident angle of the outmost edge light when the outmost edge light is not reflected by the light-extracting portion 6 and is emitted through an interface between the display panel and the air, θₐᵢᵣ can be

$$arcsin \frac{1}{n 1} ,$$

n1 denotes a refractive index of the light-modulating sub-pixel 4, which can also be understood as the refractive index of the light-emitting material corresponding to the light-modulating sub-pixel 4, δ2 is a total reflection angle when the outmost edge light is incident to the organic encapsulation layer 10 through the first inorganic encapsulation layer 9, n3 denotes a refractive index of the first inorganic encapsulation layer 9, and n4 denotes a refractive index of the organic encapsulation layer 10.

Assuming that the corresponding total reflection angle when light enters the light-extracting portion 6 through the high refractive index layer 7 is δ1,

$$δ1 = arcsin \frac{n 6}{n 7} ,$$

n6 denotes the refractive index of the light-extracting portion 6, and n7 denotes the refractive index of the high refractive index layer 7. An incident angle θ6=(90°−θ5)+(90°−θ0) at which the light is reflected on the sidewall of the light-extracting portion 6, the light-extracting portion 6 includes a bottom surface 12 close to the substrate 1 and a sidewalls 13 intersecting the bottom surface 12, θ0 denotes an angle between the sidewall 13 and the bottom surface 12, θ5 denotes an exiting angle of light entering the high refractive index layer 7 through the second inorganic encapsulation layer 11. In order to ensure that all light can be reflected by the sidewall 13 of the light-extracting portion 6, θ6 can satisfy: θ6 ∈(δ1, 90°).

According to the refraction formula, sin θ4×n5=sin θ5×n7, it is obtained:

$$θ5 = arcsin \frac{n 5 ⨯ sin θ4}{n 7} ,$$

where θ4 denotes an exiting angle of light entering the second inorganic encapsulation layer 11 through the organic encapsulation layer 10, and n5 denotes the refractive index of the second inorganic encapsulation layer 11.

Since the first inorganic encapsulation layer 9 and the second inorganic encapsulation layer 11 have a same refractive index, the exiting angle θ4 of light entering the second inorganic encapsulation layer 11 through the organic encapsulation layer 10 and the incident angle θ1 of light entering the organic encapsulation layer 10 through the first inorganic encapsulation layer 9 are equal to each other, therefore,

$$θ5 = arcsin \frac{n 5 ⨯ sin θ1}{n 7}$$

can be deduced according to

$$θ5 = arc sin \frac{n 5 \times sin θ4}{n 7} .$$

Combining the relationship between θ5 and θ6,

$$θ 1 ∈ ( \frac{( n 7 \times ( 90 ° - θ 0 )}{n 5} , \frac{n 7 \times ( 180 ° - δ1 - θ 0 )}{n 5} )$$

can be obtained.

Combining

$$θ 1 ∈ ( {θ}_{air} , δ 2 ) and θ 1 ∈ ( \frac{n 7 \times ( 90 ° - θ 0 )}{n 5} , \frac{n 7 \times ( 180 ° - δ 1 - θ 0 )}{n 5} ) ,$$

following four cases can be drawn.

In a first case, when

$$δ 2 > \frac{n 7 \times ( 180 ° - δ 1 - θ 0 )}{n 5} , {θ}_{air} < \frac{n 7 \times ( 90 ° - θ 0 )}{n 5} , θ 1 ∈ ( \frac{n 7 \times ( 90 ° - θ 0 )}{n 5} , \frac{n 7 \times ( 180 ° - δ 1 - θ 0 )}{n 5} ) .$$

In a second case, when

$$\frac{n 7 \times ( 90 ° - θ 0 )}{n 5} < δ 2 < \frac{n 7 \times ( 180 ° - δ 1 - θ 0 )}{n 5} , {θ}_{air} < \frac{n 7 * ( 90 ° - θ 0 )}{n 5} , θ 1 ∈ ( \frac{n 7 \times ( 90 ° - θ0 )}{n 5} , δ 2 ) .$$

In a third case, when

$${θ}_{air} > \frac{n 7 \times ( 90 ° - θ 0 )}{n 5} , δ 2 > \frac{n 7 \times ( 180 ° - δ 1 - θ 0 )}{n 5} , θ 1 ∈ ( {θ}_{air} , \frac{n 7 \times ( 180 ° - δ 1 - θ 0 )}{n 5} ) .$$

In a fourth case, when

$${θ}_{air} > \frac{n 7 \times ( 90 ° - θ 0 )}{n 5} , δ 2 < \frac{n 7 \times ( 180 ° - δ 1 - θ 0 )}{n 5} , θ 1 ∈ ( {θ}_{air} , δ 2 ) .$$

When θ1 satisfies any one of the above four conditions, the outmost edge light emitted by the light-modulating sub-pixel 4 can be emitted through a light exiting interface of the display panel.

In some embodiments, referring to FIG. 4, in the direction perpendicular to a plane of the display panel, a distance L between the light-extracting portion 6 and the light-modulating sub-pixel 4 satisfies L=d1×tan θ1+d2×tan θ3+d3×tan θ4, where d1 denotes a thickness of the first inorganic encapsulation layer 9, d2 denotes a thickness of the organic encapsulation layer 10, d3 denotes a thickness of the second inorganic encapsulation layer 11, and θ3 denotes an incident angle of light entering the second inorganic encapsulation layer 11 through the organic encapsulation layer 10. Since θ4=θ1, L=(d1+d3)×tan θ1+d2×tan θ3.

$$Sin θ 3 \times n 4 = sin θ4 \times n 5 , and θ 3 = arc sin \frac{n 5 \times sin θ 4}{n 4} = arcsin \frac{n 5 \times sin θ 1}{n 4} ,$$

and thus it can be obtained that

$$L = ( d 1 + d 3 ) \times tan θ 1 + d 2 \times tan ( arc sin \frac{n 5 \times sin θ 1}{n 4} ) .$$

In combination with the range of θ1 determined above, L has a maximum value Lₘₐₓ and a minimum value Lₘᵢₙ when substituting θ1 into the formula of L. When L is between Lₘₐₓ and Lₘᵢₙ, the outmost edge light emitted by the light-modulating sub-pixel 4 can be less shielded by the light-extracting portion 6, and more edge light can be reflected by the sidewall 13 of the light-extracting portion 6 and finally emitted through the light exiting interface of the display panel.

That is, in some embodiments of the present disclosure, in the direction perpendicular to the plane of the display panel, L1 and L2 can satisfy: Lₘᵢₙ≤L1≤Lₘₐₓ, and L2>Lₘₐₓ.

For example, combined with the above first case, when

$$δ 2 > \frac{n 7 \times ( 180 ° - δ 1 - θ 0 )}{n 5} and {θ}_{air} < \frac{n 7 \times ( 90 ° - θ 0 )}{n 5} ,$$

Lₘₐₓ and Lₘᵢₙ are respectively the maximum value and the minimum value of L obtained by combining

$$L = ( d 1 + d 3 ) \times tan θ 1 + d 2 \times tan ( arcsin \frac{n 5 \times sin θ 1}{n 4} ) and \\ θ 1 ∈ ( \frac{n 7 \times ( 90 ° - θ0 )}{n 5} ) , \frac{n 7 \times ( 180 ° - δ 1 - θ 0 )}{n 5} ) .$$

Combined with the above second case, when

$$\frac{n 7 \times ( 90 ° - θ 0 )}{n 5} < δ 2 < \frac{n 7 \times ( 180 ° - δ 1 - θ 0 )}{n 5} and {θ}_{air} < \frac{n 7 \times ( 90 ° - θ0 )}{n 5} ,$$

Lₘₐₓ and Lₘᵢₙ are respectively the maximum value and the minimum value of L obtained by combining

$$L = ( d 1 + d 3 ) \times tan θ 1 + d 2 \times tan ( arcsin \frac{n 5 \times sin θ 1}{n 4} ) and \\ θ 1 ∈ ( \frac{n 7 \times ( 90 ° - θ 0 )}{n 5} , δ 2 ) .$$

Combining with the above third case, when

$${θ}_{air} > \frac{n 7 \times ( 90 ° - θ 0 )}{n 5} and δ 2 > \frac{n 7 \times ( 180 ° - δ 1 - θ 0 )}{n 5} ,$$

Lₘₐₓ and Lₘᵢₙ are respectively the maximum value and the minimum value of L obtained by combining

$$L = ( d 1 + d 3 ) \times tan θ 1 + d 2 \times tan ( arcsin \frac{n 5 \times sin θ 1}{n 4} ) and \\ θ 1 ∈ ( {θ}_{air} , \frac{n 7 \times ( 180 ° - δ 1 - θ 0 )}{n 5} ) .$$

Combining the above fourth case, when

$${θ}_{air} > \frac{n 7 ⨯ ( 90 ° - θ 0 )}{n 5} and δ2 < \frac{n 7 ⨯ ( 180 ° - δ1 - θ 0 )}{n 5} ,$$

Lₘₐₓ and Lₘᵢₙ are respectively the maximum value and the minimum value of L obtained by combining

$$L = ( d 1 + d 3 ) ⨯ tan θ 1 + d 2 ⨯ tan ( arcsin \frac{n 5 ⨯ sin θ1}{n 4} ) and \\ θ1 ∈ ( {θ}_{air} , \frac{n 7 ⨯ ( 180 ° - δ1 - θ 0 )}{n 5} ) .$$

FIG. 5 is another top view of the display panel according to some embodiments of the present disclosure. In some embodiments, as shown in FIG. 5, the light-extracting portions 6 include a first light-extracting portion 14 and a second light-extracting portion 15. In the direction perpendicular to the plane of the substrate 1, the first light-extracting portion 14 is located at a side of the light-modulating sub-pixel 4 in a first direction x, and a distance between the first light-extracting portion 14 and the light-modulating sub-pixel 4 closest to the first light-extracting portion 14 is smaller than a distance between the first light-extracting portion 14 and the non-light-modulating sub-pixel 5 closest to the first light-extracting portion 14. In the direction perpendicular to the plane of the substrate 1, the second light-extracting portion 15 is located on a side of the light-modulating sub-pixel 4 in a second direction y, the second direction y intersects the first direction x, and a distance between the second light-extracting portion 15 and the light-modulating sub-pixel 4 closest to the second light-extracting portion 15 is smaller than a distance between the second light-extracting portion 15 and the non-light-modulating sub-pixel 5 closest to the second light-extracting portion 15.

By providing the light-extracting portion 6 at the side of the light-modulating sub-pixel 4 in the first direction x and providing the light-extracting portion 6 at the side of the light-modulating sub-pixel 4 in the second direction y, the first extracting portion 14 can improve the light extraction efficiency of the light emitted by the light-modulating sub-pixel 4 in the 90° direction, and the second light-extracting portion 15 can improve the light extraction efficiency of the light emitted by the light-modulating sub-pixel 4 in the 0° direction, so as to improve the uniformity of the degree of improvement of the light extraction efficiency of the light emitted by the light-modulating sub-pixel 4 in different directions.

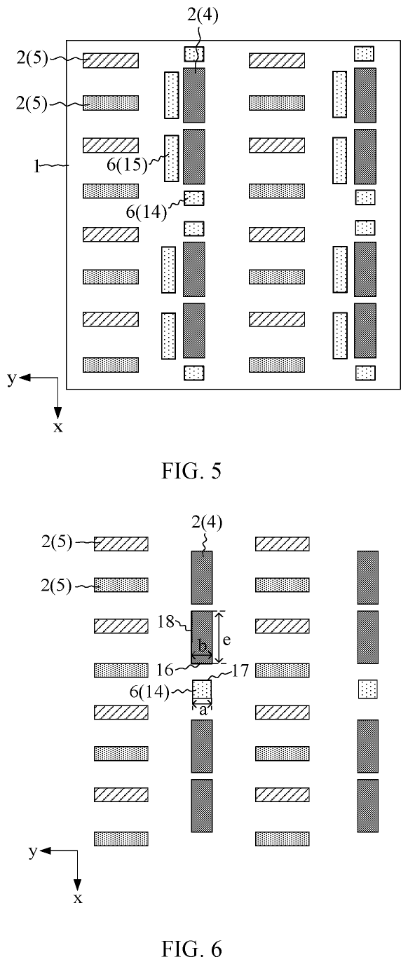

FIG. 6 is a schematic diagram of the light-extracting portion 6 according to some embodiments of the present disclosure. In some embodiments, as shown in FIG. 6, there are at least two light-modulating sub-pixels 4 that are adjacent to each other in the first direction x.

The light-extracting portions 6 include a first light-extracting portion 14, and in the direction perpendicular to the plane of the substrate 1, the first light-extracting portion 14 is located between at least two adjacent light-modulating sub-pixels 4, and the first light-extracting portion 14 does not overlap with the non-light-modulating sub-pixels 5 in the first direction x.

With the above position of the first light-extracting portion 14, in the first direction x, the first light-extracting portion 14 does not overlap with the non-light-modulating sub-pixel 5, so the first light-extracting portion 14 is far away from the non-light-modulating sub-pixel 5. In this case, the first light-extracting portion 14 can improve the light extraction efficiency of the light-modulating sub-pixels 4 without affecting the light extraction efficiency of the non-light-modulating sub-pixels 5, thereby effectively improving the difference in service life attenuation of different sub-pixels 2. Since the first light-extracting portion 14 is located between two adjacent light-modulating sub-pixels 4, a single first extracting portion 14 can improve the light extraction efficiency of both light-modulating sub-pixels 4, which reduces the number of light-extracting portions 6 that need to be arranged in the display panel while ensuring that the light-modulating sub-pixel 4 has a higher light extraction efficiency.

In some embodiments, referring to FIG. 6 again, in the direction perpendicular to the plane of the substrate 1, the light-modulating sub-pixel 4 includes a first pixel edge 16 extending along the second direction y, the second direction y intersects with the first direction x, and the first pixel edge 16 has a length b. The first light-extracting portion 14 includes a first regulation edge 17 extending along the second direction y, and the first regulation edge 17 has length a, where a≤b. In some embodiments, in the first direction x, an orthographic projection of the first regulation edge 17 is located within an orthographic projection of the first pixel edge 16.

Such configuration can ensure that the first light-extracting portion 14 improves the light extraction efficiency of the light-modulating sub-pixels 4 while the first light-extracting portion 14 and the non-light-modulating sub-pixels 5 at both sides of the first light-extracting portion 14 can be separated by a sufficient distance, so that it is greatly avoided that the first light-extracting portion 14 affects the light output of the non-light-modulating sub-pixel 5, thereby reducing the difference in service life attenuation of the light-modulating sub-pixel 4 and the non-light-modulating sub-pixel 5.

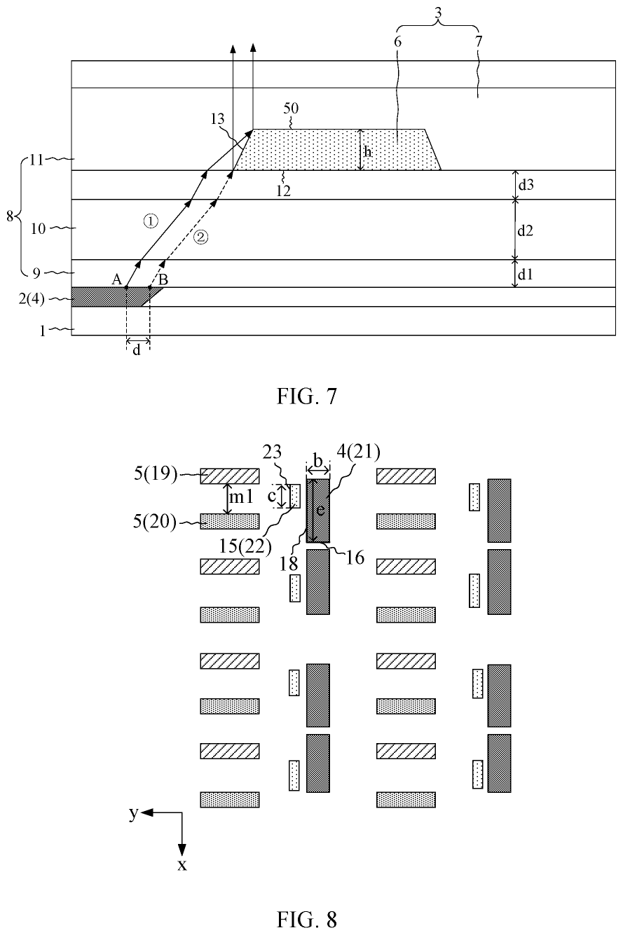

FIG. 7 is another schematic diagram of a light transmission according to some embodiments of the present disclosure. In conjunction with FIG. 4 and the above analysis of the angle range of θ1, as shown in FIG. 7, a distance between two points A and B in the light-modulating sub-pixel 4 is d, light \textcircled{1} emitting from point A is parallel to light \textcircled{2} emitted from point A, the light \textcircled{1} is reflected at the interface between the sidewall 13 of the light-extracting portion 6 and a top surface 50, and the light \textcircled{2} is reflected at the interface between the sidewall 13 of the light-extracting portion 6 and the bottom surface 12.

d=h×(tan(180°−θ5−θ0)−cot θ0), where h denotes a thickness of the light-extracting portion 6 in the direction perpendicular to the plane of the substrate 1. With

$$θ5 = arcsin \frac{n 5 ⨯ sin θ1}{n 7} ,$$

a functional relationship between d, h, θ0, and θ1 can be obtained: d=d (h, θ0, θ1).

In this case, an increasing rate of the light-extracting portion 6 to the light extraction efficiency of the light emitted by the light-modulating sub-pixel 4 is η, where

$$η = \frac{w}{D 1} ⨯ \frac{{\int }_{{θ}_{1 min}}^{{θ}_{1 max}} E ( θ 1 ) * d ( h , θ 1 , θ 0 ) d θ 1}{D 2 * {\int }_{0}^{{θ}_{a i r}} E ( θ 1 ) d θ 1} .$$

In the direction perpendicular to the plane of the substrate 1, a side of the light-modulating sub-pixel 4 close to the light-extracting portion 6 is a first side, a side of the light-modulating sub-pixel 4 intersecting with the first side is a second side, and D1 is a length of the first side. D2 is a length of the second side, w is a length of a side of the light-extracting portion 6 close to the light-modulating sub-pixel 4, E(θ1) represents a spatial energy distribution of the light emitted by the light-modulating sub-pixel 4, θ1ₘₐₓ and θ1ₘᵢₙ is a maximum value and a minimum value of θ1 determined in the above four cases, respectively.

In combination of FIG. 6, for the first light-extracting portion 14, w in the formula is a length a of the first regulation edge 17, D1 in the formula is a length of the first pixel edge 16, that is, D1=b, D2 is a length of a second pixel edge 18 intersecting the first pixel edge 16, i.e., D2=e. Bringing D2=e into the formula, it can be seen that the increasing rate of the light extraction efficiency of the first light-extracting portion 14 to the light-modulating sub-pixel 4

$$η1 = \frac{a}{b} ⨯ \frac{{\int }_{{θ}_{1 min}}^{{θ}_{1 max}} E ( θ 1 ) * d ( h , θ 1 , θ 0 ) d θ 1}{e * {\int }_{0}^{{θ}_{a i r}} E ( θ 1 ) d θ 1} .$$

In order to increase the increasing rate η1 of the light extraction efficiency of the first light-extracting portion 14 to the light-modulating sub-pixel 4, a=b. In this case, in the first direction x, an orthographic projection of the first regulation edge 17 can coincide with an orthographic projection of the first pixel edge 16.

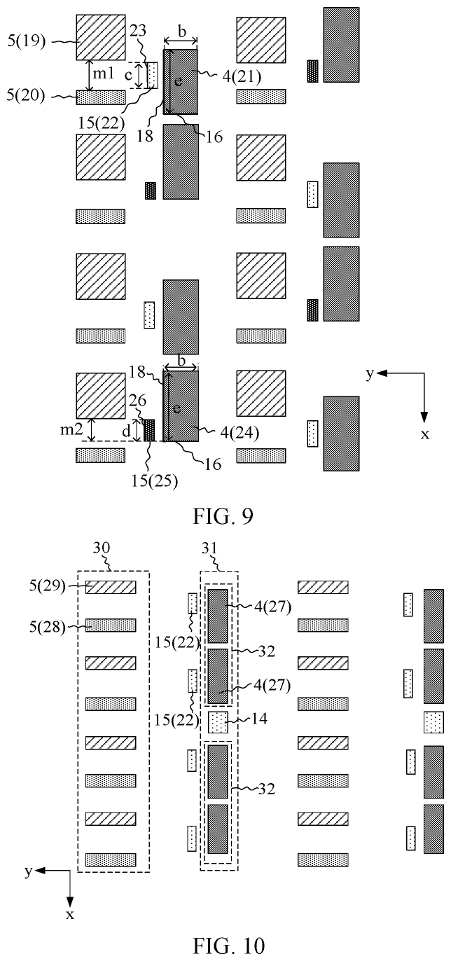

FIG. 9 is another schematic diagram of the light-extracting portion 6 provided by some embodiments of the present disclosure. In some embodiments, as shown in FIG. 9, in the second direction y, the light-modulating sub-pixel 4 overlaps with the non-light-modulating sub-pixel 5. The light-extracting portions 6 include a second light-extracting portion 15, and in the direction perpendicular to the plane of the substrate 1, the second light-extracting portion 15 is located at a side of the light-modulating sub-pixel 4 in the second direction y, and the second light-extracting portion 15 does not overlap with the non-light-modulating sub-pixel 5 in the second direction y.

Based on the position of the second light-extracting portion 15, the second light-extracting portion 15 is far away from the non-light-modulating sub-pixel 5. In this case, the second light-extracting portion 15 can increase the light extraction efficiency of the light-modulating sub-pixel 4 without affecting the light extraction efficiency of non-light-modulating sub-pixel 5, thereby effectively improving the difference in service life attenuation of different sub-pixels 2.

In some embodiments, referring to FIG. 8 again, the non-light-modulating sub-pixels 5 include a first-color non-light-modulating sub-pixel 19 and a second-color non-light-modulating sub-pixel 20. The light-modulating sub-pixels 4 include a first light-modulating sub-pixel 21, and in the second direction y, the first light-modulating sub-pixel 21 overlaps with each of the first-color non-light-modulating sub-pixel 19 and the second-color non-light-modulating sub-pixel 20. The second light-extracting portion 15 includes a second Light-extracting sub-portion A 22. In a direction perpendicular to the plane of the substrate 1, the second light-extracting sub-portion A 22 is located at a side of the first light-modulating sub-pixel 21 in the second direction y, and in the second direction y, the second light-extracting sub-portion A 22 is located in a gap formed between the first-color non-light-modulating sub-pixel 19 and the second-color non-light-modulating sub-pixel 20.

In some embodiments, referring to FIG. 8 again, the light-modulating sub-pixel 4 overlaps with each of the first-color non-light-modulating sub-pixel 19 and the second-color non-light-modulating sub-pixel 20 in the second direction y. In this case, the second light-extracting sub-portion A 22 can be provided at a side of the light-modulating sub-pixel 4 in the second direction y. FIG. 9 is another schematic diagram of the light-extracting portion 6 according to some embodiments of the present disclosure. In some embodiments, as shown in FIG. 9, at least one light-modulating sub-pixel 4 overlaps with both the first-color non-light-modulating sub-pixel 19 and the second-color non-light-modulating sub-pixel 20 in the second direction y, while at least another one light-modulating sub-pixel 4 overlaps with only the first-color non-light-modulating sub-pixel 19. In this case, the second light-extracting sub-portion A 22 is located at a side of the at least one light-modulating sub-pixel 4 that overlaps with both the first-color non-light-modulating sub-pixel 19 and the second-color non-light-modulating sub-pixel 20.

In some embodiments, in order to slow down the service life attenuation of the light-modulating sub-pixel 4, an area of the light-modulating sub-pixel 4 can be larger than both an area of the first-color non-light-modulating sub-pixel 19 and an area of the second-color non-light-modulating sub-pixel 20. The areas of the first-color non-light-modulating sub-pixel 19 and the second-color non-light-modulating sub-pixel 20 can be equal to each other, which is shown in FIG. 8, or can be different from each other, which as shown in FIG. 9.

Such configuration can ensure sufficient distances between the second light-extracting sub-portion A 22 and each of the first-color non-light-modulating sub-pixel 19 and the second-color non-light-modulating sub-pixel 20 while ensuring that the light extraction efficiency of the second light-extracting sub-portion A 22 to the first light-modulating sub-pixel 21 can be increased, thereby preventing the second light-extracting sub-portion A 22 from affecting the light output of the first-color non-light-modulating sub-pixel 19 and the light output of the second-color non-light-modulating sub-pixel 20 to a greater extent, and thus reducing the difference in service life attenuation of the first light-modulating sub-pixel 21, the first-color non-light-modulating sub-pixel 19, and the second-color non-light-modulating sub-pixel 20.

In some embodiments, referring to FIG. 8 and FIG. 9 again, in the direction perpendicular to the plane of the substrate 1, a distance between the first-color non-light-modulating sub-pixel 19 and the second-color non-light-modulating sub-pixel 20 is m1, the second light-extracting sub-portion A 22 includes a second regulation edge 23 extending along the first direction x intersecting the second direction y, and the second regulation edge 23 has a length c, where c=m1.

Combining with the derivation of the above formula for increasing efficiency it can be derived that for the second light-extracting sub-portion A 22, w in the formula is the length c of the second control side 23, D1 in the formula is the length of the second pixel side 18, i.e., D1=e, and D2 is the length of the first pixel edge 16 intersecting the second pixel edge 18, i.e., D2=b. Bring these into the formula, it can be seen that a rate η2 of the light extraction efficiency of the first light-modulating sub-pixel 21 increased by the second light-extracting sub-portion A 22 is:

$$η2 = \frac{c}{e} ⨯ \frac{{\int }_{{θ}_{1 min}}^{{θ}_{1 max}} E ( θ 1 ) * d ( h , θ 1 , θ 0 ) d θ 1}{b * {\int }_{0}^{{θ}_{a i r}} E ( θ 1 ) d θ 1} .$$

On the premise that the second light-extracting sub-portion A 22 does not overlap with the first-color non-light-modulating sub-pixel 19 and the second-color non-light-modulating sub-pixel 20 in the second direction y, setting c to m 1 can obtain a maximum value of c, which increases the rate η2 of the light extraction efficiency of the first light-modulating sub-pixel 21 increased by the second light-extracting sub-portion A 22.

In some embodiments, referring to FIG. 9 again, the non-light-modulating sub-pixels 5 include a first-color non-light-modulating sub-pixel 19 and a second-color non-light-modulating sub-pixel 20. The light-modulating sub-pixel 4 includes a second light-modulating sub-pixel 24, and the second light-modulating sub-pixel 24 overlaps with only the first-color non-light-modulating sub-pixel 19 in the second direction y. The second light-extracting portions 15 include a second light-extracting sub-portion B 25. In the direction perpendicular to the plane of the substrate 1, the second light-extracting sub-portion B 25 is located at a side of the second light-modulating sub-pixel 24 in the second direction y, and the second light-extracting sub-portion B 25 does not overlap with the first-color non-light-modulating sub-pixel 19 in the second direction y.

Such configuration can provide a sufficient distance between the second light-extracting sub-portion B 25 and each of the first-color non-light-modulating sub-pixel 19 and the second-color non-light-modulating sub-pixel 20 while ensuring that the second light-extracting sub-portion B 25 can increase the light extraction efficiency of the second light-modulating sub-pixel 24, which prevent the second light-extracting sub-portion B 25 from affecting the light output of the first-color non-light-modulating sub-pixel 19 and the second-color non-light-modulating sub-pixel 20, and thus reducing the difference in service life attenuation between the second light-modulating sub-pixel 24 and each of the first-color non-light-modulating sub-pixel 19 and the second-color non-light-modulating sub-pixel 20.

In some embodiments, referring to FIG. 9 again, in the direction perpendicular to the plane of the substrate 1, the second light-modulating sub-pixel 24 includes a first pixel edge 16 extending along the second direction y, the second direction y intersects the first direction x, and a distance between an extension line of the first pixel edge 16 and the first-color non-light-modulating sub-pixel 19 is m2. In the direction perpendicular to the plane of the substrate 1, the second light-extracting sub-portion B 25 includes a third regulation edge 26 extending along the first direction x, and a length of the third regulation edge 26 is d, where d=m2.

Combining with the derivation of the above formula for improving efficiency, for the second light-extracting sub-portion B 25, w in the formula is the length d of the third regulation edge 26, and D1 in the formula is the length of the second pixel side 18, that is, D1=e, and D2 is the length of the first pixel edge 16, that is, D2=b. Bring these into the formula, it can be seen that a rate η3 of the light extraction efficiency of the second light-modulating sub-pixel 24 increased by the second light-extracting sub-portion B 25 is

$$η 3 = \frac{d}{e} ⨯ \frac{{\int }_{{θ}_{1 min}}^{{θ}_{1 max}} E ( θ 1 ) * d ( h , θ 1 , θ 0 ) d θ 1}{b * {\int }_{0}^{{θ}_{a i r}} E ( θ 1 ) d θ 1} .$$

On the premise that the second light-extracting sub-portion B 25 does not overlap with each of the first-color non-light-modulating sub-pixel 19 and the second-color non-light-modulating sub-pixel 20 in the second direction y, setting d to m2 can obtain a maximum value of d, which can increase the rate η3 of the light extraction efficiency of the second light-modulating sub-pixel 24 increased by the second light-extracting sub-portion B 25.

In some embodiments, referring to FIG. 10, the light-modulating sub-pixels 4 include a blue sub-pixel 27, and the non-light-modulating sub-pixels 5 include a red sub-pixel 28 and a green sub-pixel 29. Exemplarily, the first-color non-light-modulating sub-pixel 19 is the green sub-pixel 29, and the second-color non-light-modulating sub-pixel 20 is the red sub-pixel 28.

Affected by the characteristics of the light-emitting material, the luminous efficiency of the blue sub-pixel 27 is relatively low, so a rate of the service life attenuation of the blue sub-pixel 27 is relatively high. In the embodiments of the present disclosure, by designing the light-modulating sub-pixel 4 as the blue sub-pixel 27, the light-modulating structure 3 can used to improve the light extraction efficiency of the blue sub-pixel 27, thereby increasing the display brightness thereof. In this way, it is no longer necessary to increase the blue light brightness by increasing the driving current flowing through the blue sub-pixel 27. When controlling the blue sub-pixel 27 to emit light, the driving current flowing through the blue sub-pixel 27 can be reduced, reducing the current density of the blue sub-pixel 27, and prolonging the service life of the blue sub-pixel 27. Meanwhile, the light-modulating structure 3 will not affect the light output of the red sub-pixel 28 and the green sub-pixel 29, so that the uniformity of the service life attenuation of the blue sub-pixel 27 and each of the red sub-pixel 28 and the green sub-pixel 29 can be improved, thereby improving color cast.

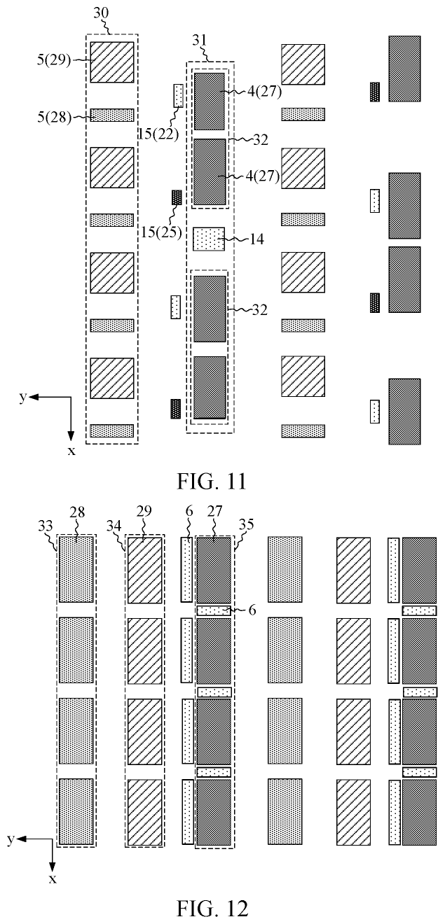

FIG. 10 is another schematic diagram of the light-extracting portion 6 according to some embodiments of the present disclosure, and FIG. 11 is another schematic diagram of the light-extracting portion 6 according to some embodiments of the present disclosure. In some embodiments, as shown in FIG. 10 and FIG. 11, the display panel includes a first pixel column 30 and a second pixel column 31 that are arranged along the second direction y. The first pixel column 30 includes green sub-pixels 29 and red sub-pixels 28 that are arranged alternately along the first direction x. The second pixel column 31 includes multiple blue pixel units 32 arranged along the first direction x, and the blue pixel unit 32 includes two blue sub-pixels 27 arranged along the first direction x. A distance between two blue sub-pixels 27 in the blue pixel unit 32 is smaller than a distance between two adjacent blue pixel units 32, and the second direction y intersects the first direction x.

The light-extracting portions 6 include a first light-extracting portion 14 and a second light-extracting portion 15. In the direction perpendicular to the plane of the substrate 1, the first light-extracting portion 14 is located between two adjacent blue pixel units 32, and the first light-extracting portion 14 does not overlap with each of the red sub-pixel 28 and the green sub-pixel 29 in the first direction x. In the direction perpendicular to the plane of the substrate 1, the second light-extracting portion 15 is located at a side of the blue sub-pixel 27 in the second direction y, and in the second direction y, the second light-extracting portion 15 does not overlap with both the red sub-pixel 28 and green sub-pixel 29.

Referring to FIG. 10, the second light-extracting portion 15 can include a second light-extracting sub-portion A 22, or, referring to FIG. 11, the second light-extracting portion 15 can include both a second light-extracting sub-portion A 22 and a second light-extracting sub-portion B 25. The configurations of the lengths of the regulation edges of the second light-extracting sub-portion A 22 and the second light-extracting sub-portion B 25 have been described in the above embodiments, and will not be repeated herein.

It can be understood that, in the process of the display panel, the sub-pixels 2 of a same color are formed by a same fine metal mask (FMM), and the fine metal mask has openings corresponding to the sub-pixels 2. In general, one opening in the fine metal mask corresponds to one sub-pixel 2. However, based on the above arrangement of the sub-pixels 2, for the fine metal mask used to form the blue sub-pixels 27, a relatively large opening can be set to correspond to two blue sub-pixels 27 in one blue pixel unit 32. In this case, light-emitting layers in the two blue sub-pixels 27 are continuous, which can also reduce the service life attenuation of the blue sub-pixels 27.

Based on the above arrangement, since there is a relatively large distance between two adjacent blue pixel units 32, arranging the first light-extracting portion 14 between two adjacent blue pixel units 32 can increase the size of the first light-extracting portion 14 in the first direction x, thereby increasing the regulation of the light output of the blue sub-pixel 27 by the first light-extracting portion 14. Meanwhile, this setting method can also prevent the first light-extracting portion 14 and the second light-extracting portion 15 from affecting the light output of the red sub-pixel 28 and the green sub-pixel 29, and can improve the uniformity of the service life attenuation of the sub-pixel 2 with three colors.

FIG. 10 and FIG. 11 only schematically illustrate two arrangements of sub-pixels 2. In some embodiments of the present disclosure, other arrangements of sub-pixels 2 can also be adopted. For example, as shown in FIG. 12, which is another schematic diagram of the arrangement of the sub-pixels 2 according to some embodiments of the present disclosure, and the sub-pixels 2 can adopt a “normal” arrangement in which the display panel includes red pixel columns 33, green pixel columns 34, and blue pixel column 35 that are alternately arranged along the second direction y. The red pixel column 33 includes multiple red sub-pixels 28 arranged along the first direction x, the green pixel column 34 includes multiple green sub-pixels 29 arranged along the first direction x, and the blue pixel column 35 includes multiple blue sub-pixels 27 arranged along the first direction x. Based on such arrangement, the light-extracting portion 6 is located at a side of the blue sub-pixel 27 in the first direction x and/or the second direction y, and a distance between the light-extracting portion 6 and the blue sub-pixel 27 closest to the light-extracting portion 6 is smaller than both a distance between the light-extracting portion 6 and the red sub-pixel 28 closest to the light-extracting portion 6 and a distance between the light-extracting portion 6 and the green sub-pixel 29 closest to the light-extracting portion 6.

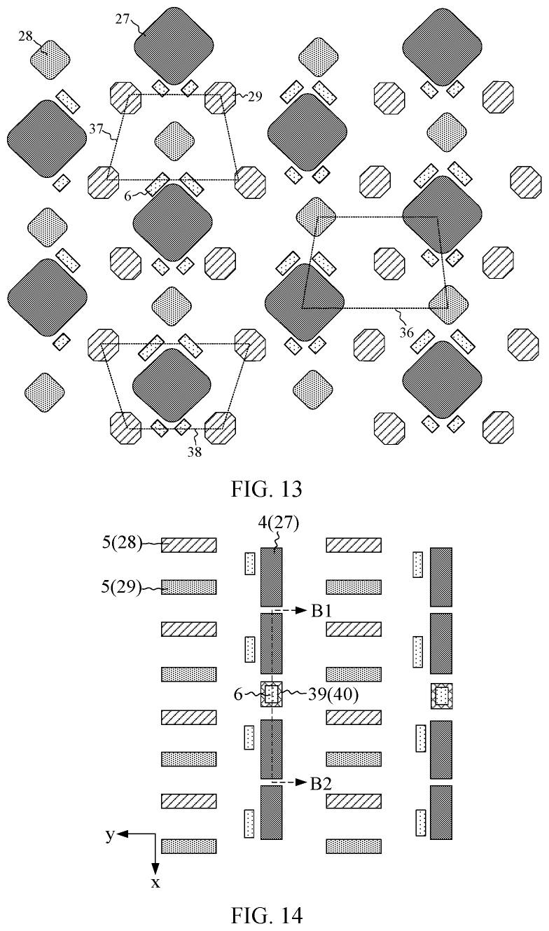

FIG. 12 is another schematic diagram of an arrangement of the sub-pixels 2 according to some embodiments of the present disclosure. In some embodiments, as shown in FIG. 13, the sub-pixels 2 can also adopt a “Windmill” arrangement where the green sub-pixel 29 is located in a first virtual trapezoid 36, and two red sub-pixels 28 and the two blue sub-pixels 27 that surround the green sub-pixel 29 are located at four corners of the first virtual trapezoid 36, respectively, that is, the green sub-pixel 29, the two red sub-pixels 28 surrounding the green sub-pixel 29, and the two blue sub-pixels 27 surrounding the green sub-pixel 29 form a pinwheel-like structure. Additionally or in the alternative, the red sub-pixel 28 is located inside the second virtual trapezoid 37, and the four green sub-pixels 29 surrounding the red sub-pixel 28 are respectively located at the four corners of the second virtual trapezoid 37, that is, the red sub-pixel 28 and the four green sub-pixels 29 surrounding the red sub-pixel 28 form a pinwheel-like structure. And/or, the blue sub-pixels 27 are located inside the third virtual trapezoid 38, and the four green sub-pixels 29 surrounding the blue sub-pixels 27 are respectively located at the four corners of the third virtual trapezoid 38, that is, the blue sub-pixels 27 and the four green sub-pixels 29 surrounding the blue sub-pixels 27 also form a pinwheel-like structure. With such arrangement, the light-extracting portion 6 is located at a side of the blue sub-pixel 27, and a distance between the light-extracting portion 6 and its nearest blue sub-pixel 27 is smaller than a distance between the light-extracting portion 6 and its nearest red sub-pixel 28 and a distance between the light-extracting portion 6 and its nearest green sub-pixel 29. Exemplarily, the light-extracting portion 6 is located at a side of the blue sub-pixel 27 in the third direction, the third direction is a direction along which the blue sub-pixel and its adjacent green sub-pixel 29 are arranged, and the light-extracting portion 6 and the green sub-pixel 29 do not overlap in the third direction.

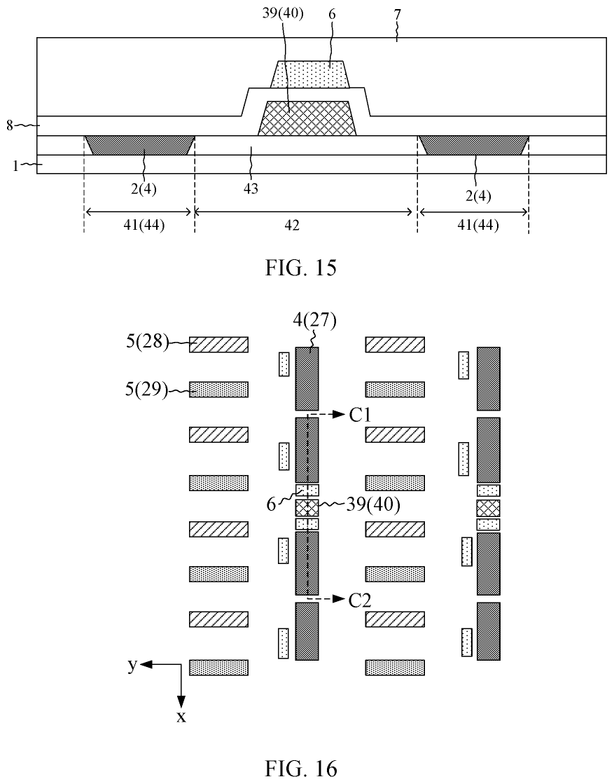

FIG. 14 is a schematic diagram illustrating positions of the light-extracting portion 6 and the first support pillar 40 according to some embodiments of the present disclosure, and FIG. 15 is a cross-sectional view of FIG. 14 along line B1-B2 according to some embodiments of the present disclosure. In some embodiments, as shown in FIG. 14 and FIG. 15, the display panel includes a support pillar 39 located at a side of the substrate 1, and the support pillar 39 includes a first support pillar 40. In the direction perpendicular to the plane of the substrate 1, the first support pillar 40 is located at a side of the light-modulating sub-pixel 4, and the first support pillar 40 at least partially overlaps with the light-extracting portion 6.

In some embodiments, referring to FIG. 15, in the direction perpendicular to the plane of the substrate 1, the support pillar 39 and the light-extracting portion 6 are both located in the middle of the two adjacent openings 44 in the pixel definition layers 43, that is, being located in the non-pixel region 42.

The support pillars 39 are generally used to stabilize the cell thickness and support the mask used to form the sub-pixels 2 in the display panel process. Generally, the support pillars 39 are located on a side of the pixel definition layer 43 facing away from the substrate 1. In some embodiments of the present disclosure, the first support pillar 40 at least partially overlaps with the light-extracting portion 6, which, on the one hand, elevates the light-extracting portion 6 by the first support pillar 40, and on the other hand, is also suitable for panel designs with small distance between adjacent sub-pixels 2, thereby being more suitable for display panels with high pixel density.

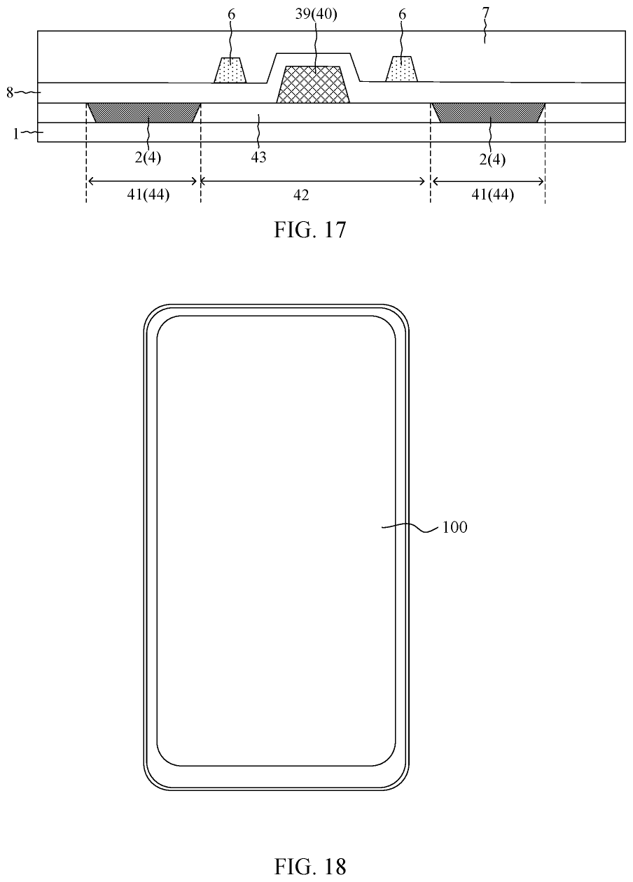

FIG. 16 is another schematic diagram illustrating positions of the light-extracting portion 6 and the first support pillar 40 according to some embodiments of the present disclosure, and FIG. 17 is a cross-sectional view of FIG. 16 along line C1-C2. In some embodiments, as shown in FIG. 16 and FIG. 17, the display panel includes a support pillar 39 located at a side of the substrate 1, and the support pillar 39 includes a first support pillar 40.

In the direction perpendicular to the plane of the substrate 1, the first support pillar 40 is located at a side of the light-modulating sub-pixel 4, and a distance between the light-extracting portion 6 and its nearest light-modulating sub-pixel 4 is smaller than a distance between the support pillar 40 and its nearest light-modulating sub-pixel 4, so as to reduce the distance between the light-extracting portion 6 and the light-modulating sub-pixel 4 as much as possible, so that the light-extracting portion 6 can increase the light extraction efficiency of the light-modulating sub-pixel 4 to a greater extent.

The distance between the light-extracting portion 6 and the light-modulating sub-pixel 4 and the distance between the first support pillar 40 and the light-modulating sub-pixel 4 can refer to a distance between the light-extracting portion 6 and the opening 44 in the pixel definition layer 43 and a distance between the first support pillar 40 and the opening 44 in the pixel definition layer 43 the light-extracting portion 6, respectively.

Based on the same concept, some embodiments of the present disclosure also provide a display device. FIG. 18 is a schematic diagram of a display device according to some embodiments of the present disclosure. As shown in FIG. 18, the display device includes the above display panel 100. The structure of the display panel 100 has been described in detail in the above embodiments, and will not be repeated herein. The display device shown in FIG. 18 is only a schematically illustrated, and the display device can be any electronic device with a display function, such as a mobile phone, a tablet computer, a laptop computer, an electronic paper book, or a television.

The above are merely some embodiments of the present disclosure and are not used to limit the present disclosure. Within the principles of the present disclosure, any modification, equivalent substitution, improvement shall fall into the scope of the present disclosure.

Finally, it can be understood that the above embodiments are only used to illustrate the technical solutions of the present disclosure, rather than limiting the technical solutions. Although the present disclosure has been described in detail with reference to the foregoing embodiments, those of ordinary skill in the art should understand that the technical solutions described in the foregoing embodiments can still be modified, or make equivalent replacement to some or all of the technical features. These modifications or replacements do not make the essence of the corresponding technical solutions deviate from the scope of the technical solutions of the embodiments of the present disclosure.

What is claimed is:

1. A display panel, comprising:
a substrate;
sub-pixels located on a side of the substrate and comprising light-modulating sub-pixels and non-light-modulating sub-pixels;
light-modulating structures located on sides of the sub-pixels facing away from the substrate, wherein each one of the light-modulating structures comprises light-extracting portions and a high refractive index layer,
wherein, in a direction perpendicular to a plane of the substrate, each of the light-extracting portions is located at a side of one of the light-modulating sub-pixels, and a first distance L1 between the light-extracting portion and one of the light-modulating sub-pixels closest to the light-extracting portion and a second distance L2 between the light-extracting portion and one of the non-light-modulating sub-pixels closest to the light-extracting portion satisfy L1<L2; and
the high refractive index layer is located on sides of the light-extracting portions facing away from the substrate and covers the sub-pixels and the light-extracting portions, and the high refractive index layer has a refractive index greater than that of the light-extracting portion.

2. The display panel according to claim 1, further comprising:
an encapsulation layer located between the sub-pixels and the light-modulating structure,
wherein the encapsulation layer comprises a first inorganic encapsulation layer, an organic encapsulation layer located on a side of the first inorganic encapsulation layer facing away from the substrate, and a second inorganic encapsulation layer located on a side of the organic encapsulation layer facing away from the substrate;
wherein the light-extracting portion comprises a bottom surface close to the substrate and a sidewall intersecting with the bottom surface, and an angle formed by the sidewall and the bottom surface is θ0;
wherein the light-modulating sub-pixel has a refractive index n1, the first inorganic encapsulation layer has a refractive index n3, the organic encapsulation layer has a refractive index n4, and the second inorganic encapsulation layer has a refractive index n5, the light-extracting portion has a refractive index n6, and the high refractive index layer has a refractive index n7;
wherein the first inorganic encapsulation layer has a thickness d1, the organic encapsulation layer has a thickness d2, and the second inorganic encapsulation layer has a thickness d3; and wherein
$$δ 2 > \frac{n 7 ⨯ ( 180 ° - δ1 - θ 0 )}{n 5} , θair < \frac{n 7 ⨯ ( 90 ° - θ0 )}{n 5} , \\ {L}_{min} \leq L 1 \leq {L}_{max} , L 2 > {L}_{max} , δ 2 = arc sin \frac{n 4}{n 3} , δ1 = arc sin \frac{n 6}{n 7} , and θair = arc sin \frac{1}{n 1} ,$$
where Lₘₐₓ and Lₘᵢₙ are respectively a maximum value and a minimum value that are obtained by combining the
$$L = ( d 1 + d 3 ) ⨯ tan θ1 + d 2 ⨯ tan ( arcsin \frac{n 5 ⨯ sin θ1}{n 4} ) with \\ θ1 ∈ ( \frac{n 7 ⨯ ( 90 ° - θ0 )}{n 5} , \frac{n 7 ⨯ ( 180 ° - δ1 - θ 0 )}{n 5} ) .$$

3. The display panel according to claim 1, further comprising:
an encapsulation layer located between the sub-pixels and the light-modulating structure,
wherein the encapsulation layer comprises a first inorganic encapsulation layer, an organic encapsulation layer located on a side of the first inorganic encapsulation layer facing away from the substrate, and a second inorganic encapsulation layer located on a side of the organic encapsulation layer facing away from the substrate;
wherein the light-extracting portion comprises a bottom surface close to the substrate and a sidewall intersecting with the bottom surface, and an angle formed by the sidewall and the bottom surface is θ0;
wherein the light-modulating sub-pixel has a refractive index n1, the first inorganic encapsulation layer has a refractive index n3, the organic encapsulation layer has a refractive index n4, and the second inorganic encapsulation layer has a refractive index n5, the light-extracting portion has a refractive index n6, and the high refractive index layer has a refractive index n7;
wherein the first inorganic encapsulation layer has a thickness d1, the organic encapsulation layer has a thickness d2, and the second inorganic encapsulation layer has a thickness d3; and wherein
$$\frac{n 7 ⨯ ( 90 ° - θ0 )}{n 5} < δ 2 < \frac{n 7 ⨯ ( 180 ° - δ1 - θ 0 )}{n 5} , \\ {θ}_{a i r} < \frac{n 7 ⨯ ( 90 ° - θ0 )}{n 5} , and {L}_{min} \leq L 1 \leq {L}_{max} , L 2 > {L}_{max} , \\ δ2 = arc sin \frac{n 4}{n 3} , δ1 = arc sin \frac{n 6}{n 7} , and θair = arc sin \frac{1}{n 1} ,$$
where Lₘₐₓ and Lₘᵢₙ are respectively a maximum value and a minimum value that are obtained by combining the
$$L = ( d 1 + d 3 ) ⨯ tan θ1 + d 2 ⨯ tan ( arcsin \frac{n 5 ⨯ sin θ1}{n 4} ) with \\ θ1 ∈ ( \frac{n 7 ⨯ ( 90 ° - θ0 )}{n 5} , δ2 ) .$$

4. The display panel according to claim 1, further comprising:
an encapsulation layer located between the sub-pixels and the light-modulating structure,
wherein the encapsulation layer comprises a first inorganic encapsulation layer, an organic encapsulation layer located on a side of the first inorganic encapsulation layer facing away from the substrate, and a second inorganic encapsulation layer located on a side of the organic encapsulation layer facing away from the substrate;
wherein the light-extracting portion comprises a bottom surface close to the substrate and a sidewall intersecting with the bottom surface, and an angle formed by the sidewall and the bottom surface is θ0;
wherein the light-modulating sub-pixel has a refractive index n1, the first inorganic encapsulation layer has a refractive index n3, the organic encapsulation layer has a refractive index n4, and the second inorganic encapsulation layer has a refractive index n5, the light-extracting portion has a refractive index n6, and the high refractive index layer has a refractive index n7;
wherein the first inorganic encapsulation layer has a thickness d1, the organic encapsulation layer has a thickness d2, and the second inorganic encapsulation layer has a thickness d3; and wherein
$$θ air > \frac{n 7 ⨯ ( 90 ° - θ0 )}{n 5} , δ2 > \frac{n 7 ⨯ ( 180 ° - δ1 - θ 0 )}{n 5} , {L}_{min} \leq L 1 \leq {L}_{max} , \\ L2 > {L}_{max} , δ2 = arc sin \frac{n 4}{n 3} , δ1 = arc sin \frac{n 6}{n 7} , and θair = arc sin \frac{1}{n 1} ,$$
where Lₘₐₓ and Lₘᵢₙ are respectively a maximum value and a minimum value that are obtained by combining the
$$L = ( d 1 + d 3 ) ⨯ tan θ1 + d 2 ⨯ tan ( arcsin \frac{n 5 ⨯ sin θ1}{n 4} ) with \\ θ 1 ∈ ( θair , \frac{n 7 ⨯ ( 18 {0}^{∘} - δ 1 - θ 0 )}{n 5} ) ,$$

5. The display panel according to claim 1, further comprising:
an encapsulation layer located between the sub-pixels and the light-modulating structure,
wherein the encapsulation layer comprises a first inorganic encapsulation layer, an organic encapsulation layer located on a side of the first inorganic encapsulation layer facing away from the substrate, and a second inorganic encapsulation layer located on a side of the organic encapsulation layer facing away from the substrate;
wherein the light-extracting portion comprises a bottom surface close to the substrate and a sidewall intersecting with the bottom surface, and an angle formed by the sidewall and the bottom surface is θ0;
wherein the light-modulating sub-pixel has a refractive index n1, the first inorganic encapsulation layer has a refractive index n3, the organic encapsulation layer has a refractive index n4, and the second inorganic encapsulation layer has a refractive index n5, the light-extracting portion has a refractive index n6, and the high refractive index layer has a refractive index n7;
wherein the first inorganic encapsulation layer has a thickness d1, the organic encapsulation layer has a thickness d2, and the second inorganic encapsulation layer has a thickness d3; and wherein
$$θair > \frac{n 7 ⨯ ( 90 ° - θ0 )}{n 5} , δ2 < \frac{n 7 ⨯ ( 180 ° - δ1 - θ0 )}{n 5} , {L}_{min} \leq L 1 \leq {L}_{max} , \\ L 2 > {L}_{max} , δ2 = arcsin \frac{n 4}{n 3} , δ1 = arcsin \frac{n 6}{n 7} , and θair = arcsin \frac{1}{n 1} ,$$
where Lₘₐₓ and Lₘᵢₙ are respectively a maximum value and a minimum value that are obtained by combining the
$$L = ( d 1 + d 3 ) ⨯ tan θ1 + d 2 ⨯ tan ( arcsin \frac{n 5 ⨯ sin θ1}{n 4} ) with θ1 ∈ ( θair , δ2 ) .$$

6. The display panel according to claim 1, wherein the light-extracting portions comprise a first light-extracting portions and a second light-extracting portions;
in a direction perpendicular to the plane of the substrate, the first light-extracting portions are located at sides of the light-modulating sub-pixels along a first direction, and a distance between one of the first light-extracting portions and one of the light-modulating sub-pixels closest to the first light-extracting portion is smaller than a distance between the first light-extracting portion and one of the non-light-modulating sub-pixels closest to the first light-extracting portion; and
in the direction perpendicular to the plane of the substrate, the second light-extracting portions are located at sides of the light-modulating sub-pixel along a second direction, the second direction intersects with the first direction, and a distance between one of the second light-extracting portions and one of the light-modulating sub-pixels closest to the second light-extracting portion is smaller than a distance between the second light-extracting portion and one of the non-light-modulating sub-pixels closest to the second light-extracting portion.

7. The display panel according to claim 1, wherein at least two of the light-modulating sub-pixels are adjacent to each other in a first direction; and
the light-extracting portions comprises first light-extracting portions, wherein, in a direction perpendicular to the plane of the substrate, one of the first light-extracting portions is located between at least two adjacent light-modulating sub-pixels, and the first light-extracting portion does not overlap with the non-light-modulating sub-pixel in the first direction.

8. The display panel according to claim 7, wherein, in the direction perpendicular to the plane of the substrate, the light-modulating sub-pixel comprises a first pixel edge extending along a second direction, the second direction intersects the first direction, and the first pixel edge has a length b; and
the first light-extracting portion comprises a first regulation edge extending along the second direction, and the first regulation edge has a length a, where a≤b.

9. The display panel according to claim 8, wherein a=b.

10. The display panel according to claim 1, wherein, in a second direction, the light-modulating sub-pixel overlaps with the non-light-modulating sub-pixel;
the light-extracting portions comprise a second light-extracting portion, wherein in a direction perpendicular to the plane of the substrate, the second light-extracting portion is located at a side of the light-modulating sub-pixel in the second direction, and the second light-extracting portion does not overlap with the non-light-modulating sub-pixel in the second direction.

11. The display panel according to claim 10, wherein the non-light-modulating sub-pixels include first-color non-light-modulating sub-pixels and second-color non-light-modulating sub-pixels;
the light-modulating sub-pixels include first light-modulating sub-pixels, and in the second direction, one of the first light-modulating sub-pixels overlaps with one of the first color non-light-modulating sub-pixels and one of the second-color non-light-modulating sub-pixels; and
the second light-extracting portions include second light-extracting sub-portion As, and in the direction perpendicular to the plane of the substrate, the second light-extracting sub-portion As are located at sides of the first light-modulating sub-pixels along the second direction, and one of the second light-extracting sub-portion As is located at a gap between one of the first-color non-light-modulating sub-pixels and one of the second-color non-light-modulating sub-pixels in the second direction.

12. The display panel according to claim 11, wherein, in the direction perpendicular to the plane of the substrate, a distance m1 is formed between the first-color non-light-modulating sub-pixel and the second-color non-light-modulating sub-pixel; and
the second light-extracting sub-portion A comprises a second regulation edge extending along a first direction, the first direction intersects with the second direction, and the second regulation edge has a length c, where c=m1.

13. The display panel according to claim 10, wherein the non-light-modulating sub-pixels include first-color non-light-modulating sub-pixels and second-color non-light-modulating sub-pixels;
the light light-modulating sub-pixels include second light-modulating sub-pixels, and in the second direction, one of the second light-modulating sub-pixels only overlaps with one of the first-color non-light-modulating sub-pixels; and
the second light-extracting portions comprises second light-extracting sub-portion Bs, and in the direction perpendicular to the plane of the substrate, the second light-extracting sub-portion Bs are located at sides of the second light-modulating sub-pixels along the second direction, and the second light-extracting sub-portion B does not overlap with the first-color non-light-modulating sub-pixel.

14. The display panel according to claim 13, wherein, in the direction perpendicular to the plane of the substrate, the second light-modulating sub-pixel includes a first pixel edge extending along the second direction, the second direction intersects the first direction, and a distance m2 is formed between an extension line of the first pixel edge and the first-color non-light-modulating sub-pixel; and
in the direction perpendicular to the plane of the substrate, the second light-extracting sub-portion B includes a third regulation edge extending along the first direction, and the third regulation edge has a length d, where d=m2.

15. The display panel according to claim 1, wherein the light-modulating sub-pixels comprise blue sub-pixels, and the non-light-modulating sub-pixels comprise red sub-pixels and green sub-pixel.

16. The display panel according to claim 15, wherein the display panel has a first pixel column and a second pixel column that are arranged along a second direction, the green sub-pixels and the red sub-pixels are arranged alternately along a first direction to form the first pixel column, blue pixel units are arranged along the first direction to form the second pixel column, wherein the blue pixel unit comprises two blue sub-pixels arranged along the first direction, and a distance between two blue sub-pixels in the blue pixel unit is smaller than a distance between two adjacent blue pixel units, and the second direction intersects the first direction;
the light-extracting portions comprises first light-extracting portions and second light-extracting portions, and in the direction perpendicular to the plane of the substrate, one of the first light-extracting portions is located between the two adjacent blue pixel units, and the first light-extracting portion does not overlap with the red sub-pixel or the green sub-pixel in the first direction; and
in the direction perpendicular to the plane of the substrate, the second light-extracting portions are located at sides of the blue sub-pixels in the second direction, and the second light-extracting portion does not overlap with the red sub-pixel or the green sub-pixel in the second direction.

17. The display panel according to claim 1, further comprising:
a support pillar located on the side of the substrate, wherein the support pillar comprises a first support pillar; and in a direction perpendicular to the plane of the substrate, the first support pillar is located at a side of the light-modulating sub-pixel, and the first support pillar at least partially overlaps with the light-extracting portion.

18. The display panel according to claim 1, further comprising:
a support pillar located on the side of the substrate, wherein the support pillar comprises a first support pillar; and in a direction perpendicular to the plane of the substrate, the first support pillar is located at a side of the light-modulating sub-pixel, and a distance between the light-extracting portion and the light-modulating sub-pixel closest to the light-extracting portion is smaller than a distance between the first support pillar and the light-modulating sub-pixel closest to the first support pillar.

19. A display device, comprising a display panel, wherein the display panel comprises:
a substrate;
sub-pixels located on a side of the substrate and comprising light-modulating sub-pixels and non-light-modulating sub-pixels;
light-modulating structures located on sides of the sub-pixels facing away from the substrate, wherein each one of the light-modulating structures comprises light-extracting portions and a high refractive index layer,
wherein, in a direction perpendicular to a plane of the substrate, each of the light-extracting portions is located at a side of one of the light-modulating sub-pixels, and a first distance L1 between the light-extracting portion and one of the light-modulating sub-pixels closest to the light-extracting portion and a second distance L2 between the light-extracting portion and one of the non-light-modulating sub-pixels closest to the light-extracting portion satisfy L1<L2; and
the high refractive index layer is located on sides of the light-extracting portions facing away from the substrate and covers the sub-pixels and the light-extracting portions, and the high refractive index layer has a refractive index greater than that of the light-extracting portion.
